(19) United States
(12) Patent Application Publication
(10) Pub. No.: US 2014/0252561 A1
(43) Pub. Date: Sep. 11, 2014

(54) VIA-ENABLED PACKAGE-ON-PACKAGE

(71) Applicant: QUALCOMM INCORPORATED, San Diego, CA (US)

(72) Inventors: Durodami Joscelyn Lisk, San Diego, CA (US); Vidhya Ramachandran, San Diego, CA (US); Jae Sik Lee, San Diego, CA (US)

(73) Assignee: QUALCOMM Incorporated, San Diego, CA (US)

(21) Appl. No.: 13/791,223

(22) Filed: Mar. 8, 2013

(51) Int. Cl. H01L 23/538; H01L 25/00

(52) U.S. Cl. CPC H01L 23/5384; H01L 25/50
USPC 257/621; 438/108

(57) ABSTRACT

A via-enabled package-on-package circuit includes a first package including a first package die having a plurality of through substrate vias (TSVs). The TSVs are configured to carry the input/output signaling for at least one second package die.

### TECHNICAL FIELD

This application relates to integrated circuit packaging, and more particularly to a package-on-package (PoP) structure in which the bottom package includes through substrate vias (TSVs).

### BACKGROUND

Package-on-package (PoP) structures have been developed for applications such as cellular telephones and other portable devices in which circuit board space must be conserved. The top package is typically a memory package whereas the bottom package is generally a processor package. PoP technology has proven to be quite popular as compared to other approaches such a stacked-die circuit. For example, a manufacturer can readily substitute different memory packages in a PoP circuit as opposed to being tied to a particular memory, which lowers costs. Moreover, the top and bottom packages may be tested independently. In contrast, a bad die in a stacked-die design requires rejection of the remaining good die.

Although the packaging of integrated circuits using PoP structures is quite popular, challenges remain in this packaging process such as reducing the interconnect pitch between the top package and the bottom package. As technology advances, the bus width between the top package and the bottom package increases accordingly. But the ball pitch or through molded via pitch between the top substrate and the bottom substrate can only accommodate a certain number of signals. To address the small-pitch requirements, a molded-embedded PoP (MEP) has been developed. In an MEP, an additional substrate may be included between the top and bottom packages. For example, FIG. 1 illustrates an MEP 100 that includes a top package 105 coupled to an additional substrate 110. In this fashion, additional substrate 110 can redistribute signals to assist in accommodating the increased number of signals to and from the dies in top package 105. However, even with additional substrate 110, there remains a limitation with regard to the number of interconnects 120 such as solder balls or pillars that can be placed between additional substrate 110 and a bottom package substrate 111 because interconnects 120 must be placed outside of a bottom package die 115. FIG. 2 illustrates how interconnects 120 are arranged on a bottom surface of additional substrate 110 about an area 200 facing bottom die 115. Interconnects 120 are thus limited to an annular outer region of additional substrate 110 outside of area 200. Interconnects 120 are similarly limited to an annular outer region of bottom package substrate 111, which in turn limits the number of I/O signals that can be exchanged between the top package and the bottom package. An analogous interconnect restriction exists in other conventional PoPs.

Accordingly, there is a need in the art for improved PoP architectures to provide increased density.

### SUMMARY

A via-enabled package-on-package (PoP) circuit includes a first package die having a plurality of through substrate vias (TSVs). The TSVs are configured to carry the input/output signaling for at least one second package die in an adjoining second package. As used herein, “input/output signaling” includes all the electrical signals received by the second package die(s), including power and ground. Similarly, “input/output signaling” includes all output signals from the second package die(s).

Since the TSVs in the first package die carry the input/output signaling for the second package dies(s), no through mold via pillars or solder ball interconnects between the second package substrate and the first package substrate are needed to accommodate the input/output signaling. This is quite advantageous because the first package substrate may then be sized to just accommodate the first package die. In contrast, a conventional PoP bottom package substrate requires a substantial unoccupied first package substrate area to accommodate the interconnects to the second package substrate.

Although the first package die may include a backside redistribution layer to increase routing options for the input/output signaling to the second package, a TSV-containing interposer may also be arranged between the second package substrate and the first package die to aid in the redistribution of the input/output signaling. The interposer may be passive or may include active devices analogous to those in the first package die. Regardless of whether an interposer is included, the resulting TSV-enabled PoP (TEP) can advantageously accommodate a large number of input/output signals to the top package because of the high pitch density for TSVs across the surface area of the bottom package die.

### BRIEF DESCRIPTION OF THE DRAWINGS

FIG. 1 is a cross-sectional view of a prior art molded-embedded PoP (MEP).

FIG. 2 is a plan view of a bottom-package facing surface for the additional substrate in the MEP of FIG. 1.

FIG. 3A is a cross-sectional view of a through silicon stacking (TSS) enabled PoP (TEP) including an interposer.

FIG. 3B is a cross-sectional view of a TEP without an interposer.

FIG. 4 is a plan view of a bottom-package-facing surface for the top package substrate in the TEP of FIGS. 3A and 3B.

FIG. 5 is a cross-sectional view of a TEP bottom package during an initial manufacturing step.

FIG. 6 is a cross-sectional view of the TEP bottom package of FIG. 5 after a subsequent manufacturing step.

FIG. 7 is a cross-sectional view of the TEP bottom package of FIG. 6 after a final manufacturing step.

FIG. 8 is a cross-sectional view of a completed TEP including the TEP bottom package of FIG. 7.

FIG. 9 is a cross-sectional view of a TEP including a plurality of interposers.

FIG. 10 illustrates a plurality of electronic systems incorporating a TEP in accordance with embodiments disclosed herein.

### DETAILED DESCRIPTION

To address the need in the art to accommodate the increasing number of input and output signals for the top packages die (or dies), an improved package-on-package (PoP) structure is provided that does not suffer from the package-to-package interconnect limitations of conventional PoPs.

### Overview

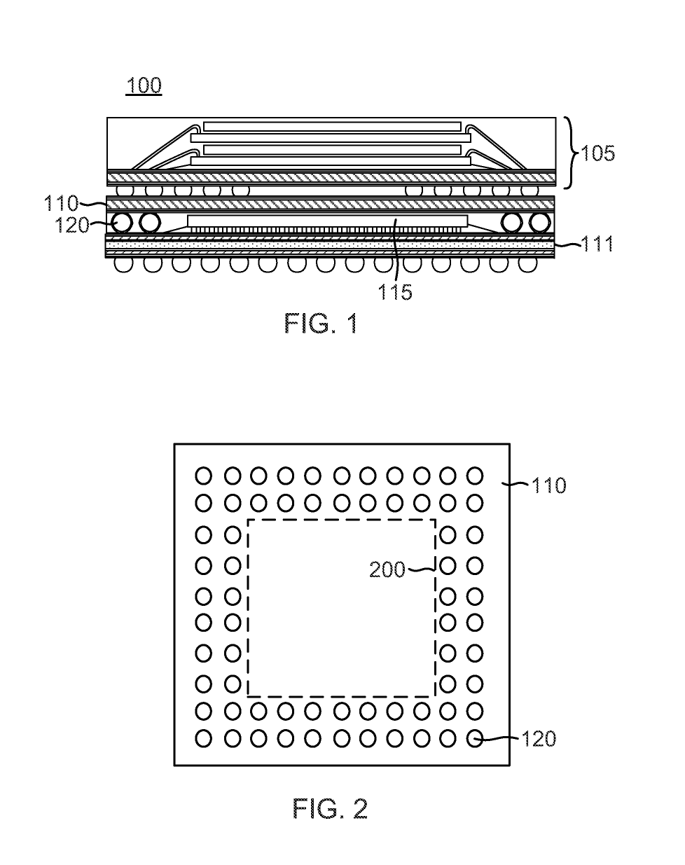

In the improved PoP disclosed herein, the first package die includes a plurality of through substrate vias (TSVs) to accommodate the input and output signaling needs of a second package die (or dies). The whole area of the first package die can thus be used for the interconnects to the second package. In contrast, a conventional PoP such as MEP 100 of FIG. 1 is restricted to the area outside of the first package die as discussed above.

To avoid any ambiguity as to what is a “top” vs “bottom” package, the bottom package for the improved PoP architectures disclosed herein is referred as a first package. Similarly, the top package is referred to as a second package. The improved PoP architectures disclosed herein can accommodate a substantially higher number of I/O signals for the second package die because the first package die area is then available to accommodate the I/O signals through its TSVs. In addition, the first package substrate size may be reduced as no substantial surface area for the first package substrate is necessary outside the surface area necessary to accommodate the footprint of the first package die. In contrast, conventional PoPs require an annular outer region on the first package substrate outside of the first package die footprint to have a sufficient size to accommodate the package-to-package interconnects. The resulting increased size of the first package substrate increases the likelihood of warping for conventional PoPs. But the improved PoPs disclosed herein advantageously can reduce warpage through the reduced size of the first package substrate. Moreover, the mold through vias or other techniques used to form conventional package-to-package interconnects are unnecessary for the improved PoPs disclosed.

The following discussion will assume without loss of generality that the first package die is a silicon die such that the through substrate vias it contains are through silicon vias. But it will be appreciated that the packaging concepts and architectures disclosed herein are widely applicable to other types of semiconductor dies. As known in the packaging arts, the process used to construct stacked devices using through silicon vias is known as a through silicon stacking (TSS) process. The resulting improved PoP disclosed herein is thus denoted as a TSS-enabled PoP (TEP). A TEP may include an interposer to provide enhanced redistribution of the input/output (I/O) signaling between its first and second packages. Alternatively, a TEP may have the first and second packages coupled together through interconnects without the user of an interposer. An interposer-containing embodiment will be discussed first followed by discussion of a directly-coupled embodiment (no interposer).

### TSS-Enabled PoP Including an Interposer

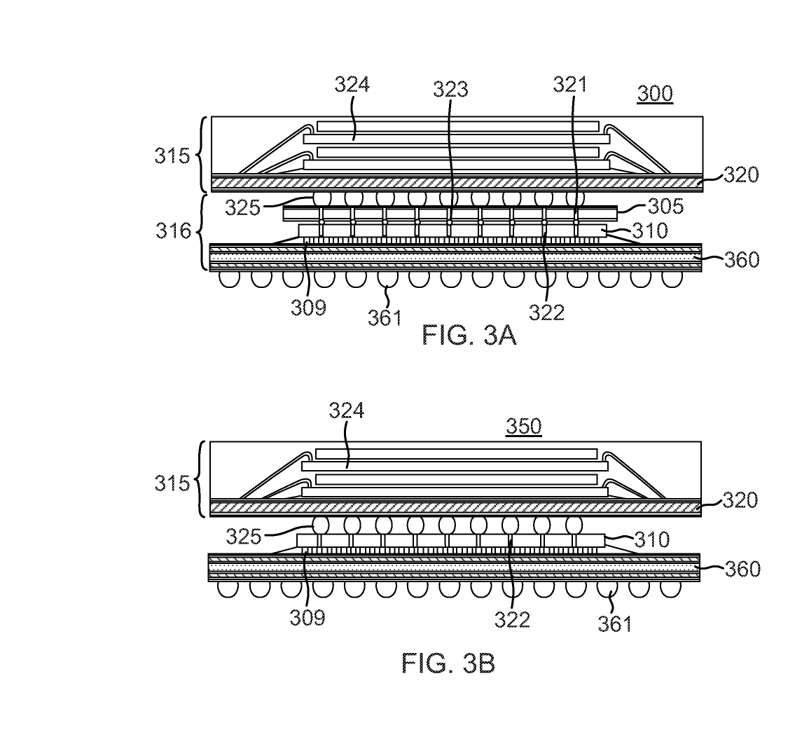

FIG. 3A illustrates an example TSS-enabled PoP (TEP) 300. A second package 315 includes a second package substrate 320 as is conventional in the PoP arts. A first package 316 includes a first package substrate 360 on which a first package die 310 is mounted using interconnects such as controlled collapse chip connection (C4) flip-chip bumps 309 as is also conventional in the PoP arts. First package substrate 360 and second package substrate 320 may each comprise an organic substrate, a semiconductor substrate such as silicon, glass, ceramic, or other suitable materials. Regardless of what materials are used to construct the package substrates, no interconnects 120 as discussed with regard to MEP 100 are necessary to accommodate the input/output (I/O) signaling for a plurality of second package dies 324 in second package 315. Instead, through silicon vias 322 in first package die 310 accommodate all the I/O signaling for second package dies 324. As used herein, “input/output signaling” includes all the electrical signals received by the second package die(s), including power and ground. Similarly, “input/output signaling” includes all output signals from the second package die(s). Alternative embodiments for TEP 300 may include just a single second package die 324 instead of a plurality of such dies.

The terms “first package” and “second package” are used herein simply to denote the different packages as is known in the PoP arts. In that regard, first package 316 of FIG. 3A corresponds to a ‘bottom package” as that term is used in the PoP arts. Similarly second package 315 corresponds to a “top package” as that term is used in the PoP arts. But such references to “top” or “bottom” are not tied to any particular reference system. In other words, a bottom package does not become a top package simply because a PoP is flipped over.

Because virtually the entire area of first package die 310 may be used for through silicon vias 322, the interconnect restrictions in PoP technology with regard to the second package die I/O are avoided. In contrast, prior art PoP architectures require the interconnects between the top package substrate and the bottom package substrate to avoid the substrate area on the bottom package substrate occupied by the bottom package die such as discussed above with regard to MEP 100. Prior-art PoP architectures thus have limited signal density as compared to the improved PoPs disclosed herein because the package-to-package interconnects are not limited to a placement on the peripheral of the bottom package substrate.

TEP 300 includes an interposer 305 having through substrate vias (TSVs) 321 that couple to through silicon vias 322 in first package die 310 through corresponding interconnects such as micro-bumps 323. Interposer 305 may comprise a semiconductor substrate such as silicon, glass, or other suitable materials. Should interposer 305 comprise a silicon substrate, TSVs 321 are through silicon vias. On the other hand, should interposer 305 comprise glass, TSVs 332 are through glass vias (TGVs). The following discussion will assume without loss of generality that TSVs 321 are through silicon vias.

Interposer 305 allows for additional redistribution of the I/O signaling to second package dies 324. Alternatively, through silicon vias 321 in interposer 305 may couple to the first package die's through silicon vias 322 through a backside redistribution layer (not illustrated) on the backside of first package die 310. Pads (not illustrated) on a lower surface of second package substrate 320 couple to the interposer through silicon vias 321 through interconnects such as bumps 325. More generally, second package substrate 320 may be considered to have a first surface and an opposing second surface. Second package dies 324 are mounted on the first surface of second package substrate 320 whereas bumps 325 connect to the opposing second surface of second package substrate 320.

In TEP 300, second package dies 324 are wire-bonded to second package substrate 320 although other mounting technologies may be used such as surface mounting. The wire bonds carry the I/O signaling between second package dies 324 and second package substrate 320. In turn, the I/O signaling for second package dies 324 is carried between second package substrate 320 and interposer 305 through bumps 325. Finally, the I/O signaling for second package dies 324 is carried between interposer 305 and first package die 310 through interposer through silicon vias 321 and first package die's through silicon vias 322. Some I/O signaling for second package dies 324 may originate from or be transmitted to external devices. Such external device I/O would be carried between interposer 305 and the external devices through though silicon vias 322 in first package die 310, bumps 309, first package substrate 360 and balls 361 on a lower surface of first package substrate 360. Interposer 305 may include active devices and/or passive components in some embodiments.

As used herein, “bump” is used to denote a structure such as a solder ball or bump. In addition, this term will be understood to also include structures such as copper pillars. In that regard, bumps 325 refer generically to the interconnecting structures that couple from pads on a bottom surface of second package substrate 320 to through silicon vias 321 on interposer 305.

### Directly-Coupled TSS-Enabled PoP (No Interposer)

FIG. 3B illustrates an alternative embodiment in which a TEP 350 does not include an interposer. Bumps 325 on pads on a lower surface of second package substrate 320 thus couple directly through first package die pads (not illustrated) to first package die through silicon vias 322 (or are coupled to through silicon vias 322 through a backside redistribution layer). As compared to TEP 300, TEP 350 requires fewer manufacturing steps. However, interposer 305 enables additional redistribution of the I/O signaling to second package dies 324. Bumps 325 may comprise interconnects such as copper pillars (micro-bumps), direct metal-to-metal bonds, or collapsed collapse chip connection (C4) bumps or solder balls.

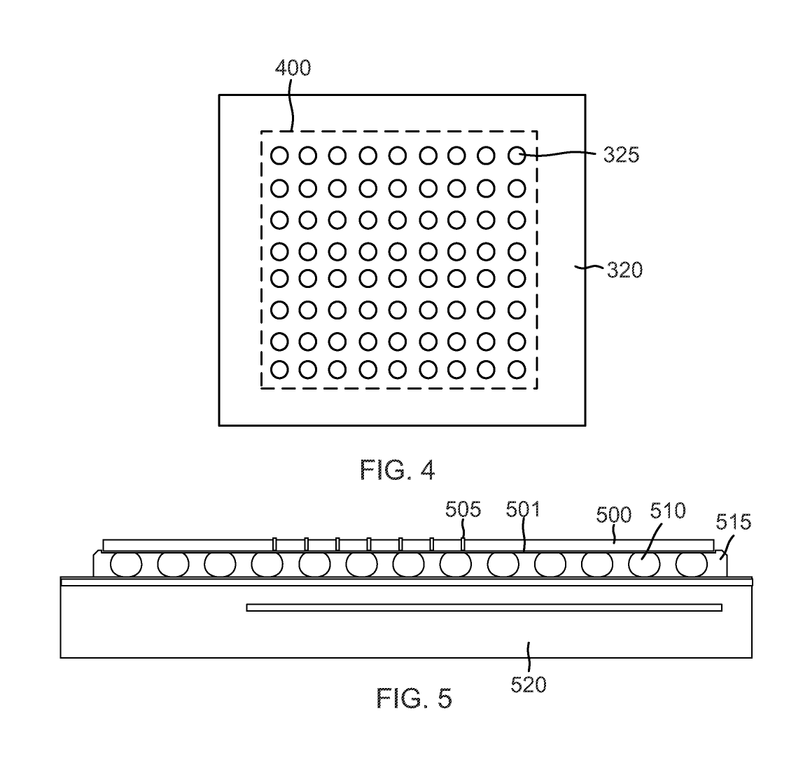

Regardless of whether an interposer is included or not, bumps 325 are not restricted to an annular region outside of the area occupied by first package die 310 in direct contrast to conventional PoPs such as MEP 100. FIG. 4 illustrates a plan view of a lower surface of second package substrate 320 to show how bumps 325 may use the entire area 400 that faces either first package die 310 (for an interposer-less embodiment such as TEP 350) or interposer 305 (in an interposer-containing embodiment such as TEP 300). In this fashion, substantially more I/O signals can be accommodated as compared to a conventional PoP embodiment. Moreover, because second package substrate 320 can receive bumps 325 across the entire surface area 400 facing first package die 310 (or interposer 305), the size of second package substrate 320 and first package substrate 360 may be reduced accordingly. In contrast, MEP 100 would need larger substrate sizes in that it must place its interconnects 120 outside of bottom die 115. In this fashion, the TEPs disclosed herein advantageously will have less warpage as compared to analogous MEPs in that warpage depends upon (among other things), the size of the substrates for the top and bottom packages.

### Example Methods of Manufacture

The manufacture of a first package for an interposer-containing TEP embodiment will now be discussed with regard to FIGS. 5 through 8. The manufacturing process uses a first package die 500 that incorporates through silicon vias 505 to accommodate not only the I/O signaling between first package die 500 and the second package dies but also for external I/O signaling to the second package die (or dies). For example, through silicon vias 505 may accommodate ground and power needs for the second package dies. As shown in FIG. 5, pads (not illustrated) on an active surface 501 for first package die 500 are mounted through flip-chip bumps 510 to corresponding pads (also not shown for illustration clarity) on a first package substrate 520. However, it will be appreciated that in alternative embodiments, the active surface orientation of first package die 500 may be reversed. In other words, the advantageous TSS-enabled PoP concepts disclosed herein may be applied to any active surface orientation. An underfill 515 such as an epoxy or other polymeric material may then be applied using capillary action. Alternatively, underfill 515 may be pre-applied at the same time bumps 510 are applied.

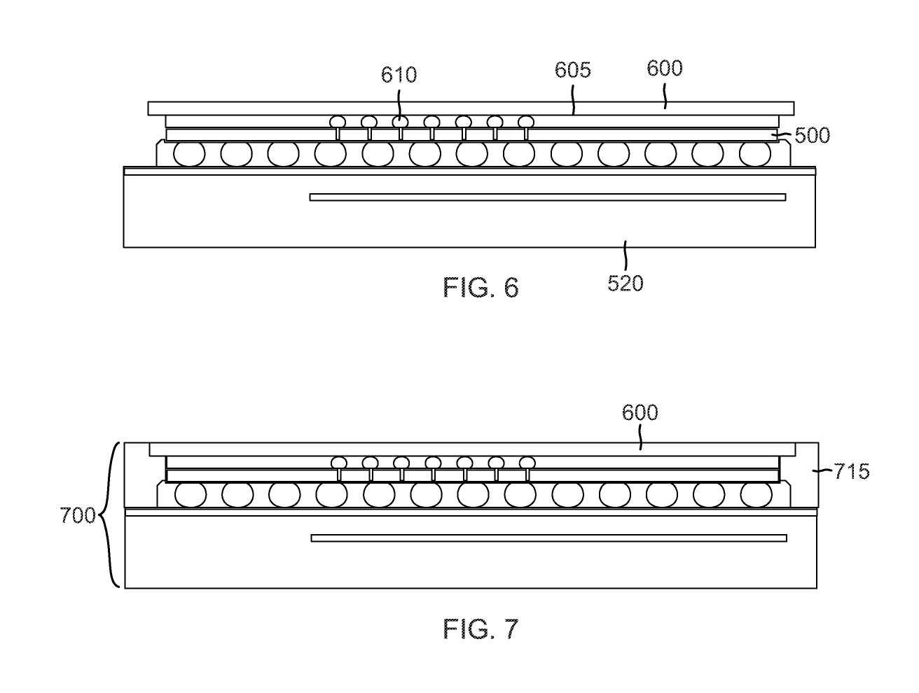

A through-silicon-via-fabricated interposer 600 may then be bonded to a back surface 605 of first package die 500 as shown in FIG. 6. For illustration clarity, the through silicon vias in interposer 600 are not shown. Bumps 610 couple pads on first package die 500 to corresponding pads on interposer 600 in response to thermo-compression. Alternatively, other bonding techniques may be used to bond interposer 600 to first package die 500 such as reflow and thermosonic bonding.

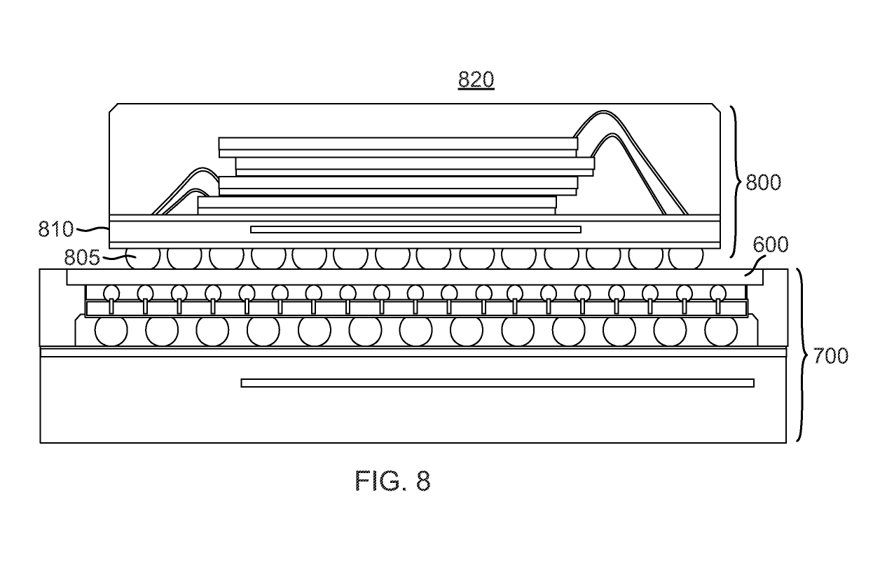

Mold compound 715 may then be applied to complete a TEP first package 700 as shown in FIG. 7. An upper surface of interposer 600 is exposed in mold compound 715 such that mold compound 715 only partially encases interposer 600. In this fashion, pads (not illustrated) on the exposed surface of interposer 600 may then be bonded as shown in FIG. 8 through interconnects 805 to corresponding pads on a lower surface of a second package substrate 810 for a second package 800 to complete the manufacture of an interposer-containing TEP 820.

### Additional Features and Embodiments

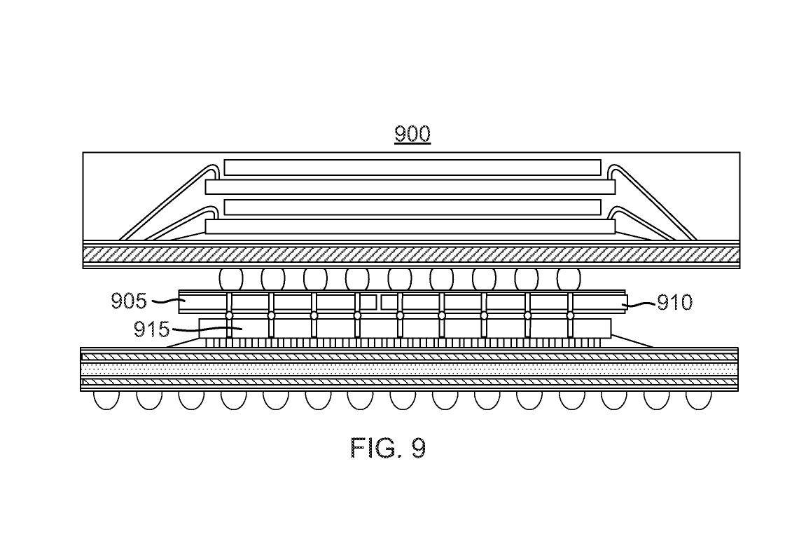

As discussed above, for TEP embodiments that include an interposer, the interposer may be passive or contain active elements. In that regard, an active interposer comprises another die comparable to the first package die discussed above. Several such TSV-containing dies could be stacked within the first package. Moreover, multiple interposers may be used in parallel as shown for TEP 900 of FIG. 9. In particular, an interposer 905 and an interposer 910 both face a back surface of first package die 915. In that regard, interposers 905 and interposer 910 are arranged in parallel in a single layer as opposed to being stacked.

Referring again to first package die 310, first package die 310 may be considered to include a means for carrying the input/output signaling for at least one second package die. In one embodiment, such a means comprises TSVs 322. In an alternative embodiment, the means may comprise deep diffusion regions that couple between pads on a back surface of first package die 310 and active circuitry on an active front surface for first package die 310.

### Example Electronic Systems

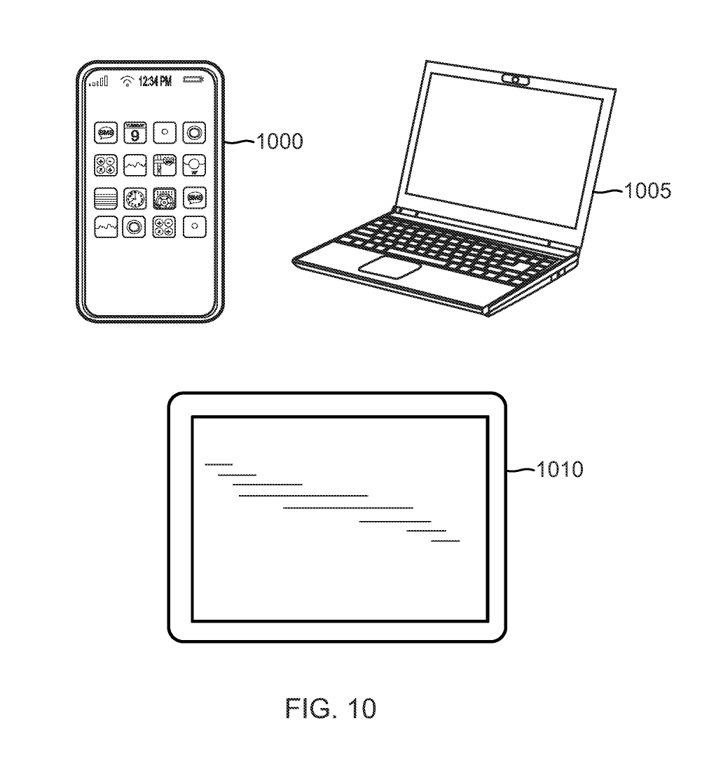

It will be appreciated that the TEP structures disclosed herein may be incorporated into a wide variety of electronic systems. For example, as shown in FIG. 10, a cell phone 1000, a laptop 1005, and a tablet PC 1010 may all include a TEP constructed in accordance with the disclosure. Other exemplary electronic systems such as a music player, a video player, a communication device, and a personal computer may also be configured with TEPs in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. An integrated circuit package, comprising:
a first package including a first package substrate and a first package die mounted thereon, wherein the first package die includes a plurality of first through substrate vias (TSVs); and
a second package including a second package substrate and at least one second package die mounted on a first surface of the second package substrate, the second package substrate having an opposing second surface having attached thereon a plurality of first interconnects, wherein the first TSVs are configured to couple to the at least one second package die through the first interconnects such that the input/output signaling for the at least one second package die is conducted by the first TSVs.

2. The integrated circuit package of claim 1, further comprising an interposer arranged between the first package die and the second package substrate, wherein the interposer includes a plurality of second TSVs coupled to the first TSVs through a plurality of second interconnects.

3. The integrated circuit package of claim 2, wherein the first package die comprises a silicon die and the first TSVs comprise first through silicon vias, ad wherein the interposer comprises a silicon substrate and the second TSVs comprise second through silicon vias.

4. The integrated circuit package of claim 1, wherein the at least one second package die comprises a plurality of second package dies.

5. The integrated circuit package of claim 4, wherein the second package dies are wire bonded to the first surface of the second package substrate.

6. The integrated circuit package of claim 1, wherein the first package die has an active first surface coupled to a first surface of the first package substrate through a plurality of second interconnects.

7. The integrated circuit package of claim 6, wherein the plurality of second interconnects comprise flip-chip interconnects.

8. The integrated circuit package of claim 2, wherein the interposer comprises a plurality of stacked interposers.

9. The integrated circuit package of claim 2, wherein the interposer comprises a plurality of interposers arranged in parallel in a single layer between the second package substrate and the first package die.

10. The integrated circuit package of claim 2, wherein the interposer includes a plurality of active devices.

11. The integrated circuit package of claim 6, wherein the first package die includes a backside redistribution layer on an opposing second surface of the first package die.

12. The integrated circuit package of claim 1, wherein the integrated circuit package is incorporated into at least one of a cellphone, a laptop, a tablet, a music player, a communication device, a computer, and a video player.

13. A method, comprising:
mounting a first package die onto a first package substrate, wherein the first package die includes a plurality of first through substrate vias (TSVs), the first package die having a first surface facing the first package substrate and an opposing backside surface; and
mounting an interposer including a plurality of second TSVs to the back surface of the first package die such that the plurality of first TSVs couple through a plurality of interconnects to the plurality of second TSVs, wherein the first TSVs and the second TSVs are configured to conduct the input/output signaling for at least one second package die.

14. The method of claim 13, wherein mounting the first package die onto the first package substrate comprises flip-chip mounting the first surface of the first package die onto a first surface of the first package substrate.

15. The method of claim 13, wherein mounting the interposer comprises thermo-compression bonding a first surface of the interposer through the plurality of interconnects to the back surface of the first package die to form a first package.

16. The method of claim 15, further comprising mounting a second package including at least one second package die onto the first package.

17. The method of claim 15, wherein the interposer comprises glass and wherein the plurality of second TSVs comprises a plurality of glass through vias (TGVs).

18. A first package for a package-on-package circuit, comprising:
a first package substrate; and
a first package substrate, wherein the first package die includes a plurality of first through substrate vias (TSVs) configured to carry the input/output signaling for at least one second package die.

19. The bottom package of claim 17, further comprising an interposer including a plurality of second TSVs coupled to the plurality of first TSVs.

20. The first package of claim 18, wherein the interposer comprises a plurality of interposers.

21. An integrated circuit package, comprising:
a first package including a first package substrate and a first package die mounted thereon; and
a second package including a second package substrate and at least one second package die mounted on a first surface of the second package substrate, wherein the first package die includes a means for carrying the input/output signaling for the at least one second package die.

22. The integrated circuit package of claim 21, wherein the means comprises a plurality of through substrate vias (TSVs).

23. The integrated circuit package of claim 21, wherein the means comprises a plurality of exposed deep diffusion regions.

24. The integrated circuit package of claim 21, further comprising an interposer including a plurality of through substrate vias coupled between the means and the second package substrate.

25. The integrated circuit package of claim 24, wherein the interposer comprises a glass interposer and wherein the through substrate vias are through glass vias.

26. The integrated circuit package of claim 24, wherein the interposer comprises a silicon interposer and wherein the through substrate vias are through silicon vias.

27. The integrated circuit package of claim 21, wherein the at least one second package die comprises a plurality of second package dies.

28. The integrated circuit package of claim 27, wherein the second package dies are wire bonded to the first surface of the second package substrate.
